(19) United States
(12) Patent Application Publication
(10) Pub. No.: US 2022/0261055 A1
(43) Pub. Date: Aug. 18, 2022

(54) ELECTRONIC DEVICE AND METHOD FOR CONTROLLING THE ELECTRONIC DEVICE

(71) Applicant: Sharp NEC Display Solutions, Ltd., Tokyo (JP)

(72) Inventor: Akira UCHIYAMA, Tokyo (JP)

(21) Appl. No.: 17/623,130

(22) PCT Filed: Jul. 8, 2019
(86) PCT No.: PCT/JP2019/026922

§ 371 Date: Dec. 27, 2021

(51) Int. Cl. G06F 1/26; G06F 1/3212; H03K 19/017

(52) U.S. Cl. CPC G06F 1/263; H03K 19/01742; G06F 1/3212; G06F 1/266

(57) ABSTRACT

One aspect of the present invention is an electronic device connectable to an external device by using a communication device and capable of supplying and receiving power to and from the external device. The electronic device includes: a battery; a power supply switch that supplies power from the battery to the external device; a power reception switch that receives power from the external device to the battery; a computation unit that performs setting of power supply and reception roles with the external device, which turns on either one of the power supply switch and the power reception switch, according to a result of comparison between a remaining battery level of the battery and a remaining battery level of a battery of the external device; and a power supply and reception management unit that, according to the setting of the power supply and reception roles with the external device, turns on the power supply switch when the electronic device becomes a source device, and turns on the power reception switch when the electronic device becomes a sink device.

### TECHNICAL FIELD

The present invention relates to an electronic device and a method for controlling the electronic device.

### BACKGROUND ART

In recent years, the number of electronic devices compatible with USB Type-C, which enables power supply and reception of large currents, is increasing in the USB standard. Normally, the power supply and reception up to 15 W is enabled via VBUS, which is a power supply circuit for the Type-C cable. In the technology aimed at quick charging, there is a USB Power Delivery (hereinafter referred to as UPD) function which enables up to 100 W.

If a USB Type-C compatible device is a Dual Role Port (hereinafter referred to as DRP) capable of both power supply and power reception, the roles of the power supply and the power reception by USB Type-C are exchangeable. That is, if a port of an electronic device compatible with USB Type-C is a Downstream Facing Port (hereinafter referred to as DFP), the power supply is enabled; if it is an Upstream Facing Port (hereinafter referred to as UPF), the power reception is enabled; and if it is a DRP which can be both ports, a connected device can mutually be both a power supplying side (hereinafter referred to as source) and a power receiving side (hereinafter referred to as sink).

The rolls of the DRP are set when a connection of a USB Type-C device is detected. For example, when electronic devices connected to the USB Type-C device are both DRPs, the rolls of the DRPs are set randomly according to a cycle of the pull-up and pull-down operations of a resistor device on a circuit that controls the power supply and reception. On the other hand, when one of the devices connected to the device has only the roll function of either the power supply or the power reception, in consideration of this, the roll of the other one of the electronic devices is set so as to be relative to that of the one of the electronic devices.

When performing the power supply and reception between a projection device and an arbitrary device using only a USB Type-C device, if the electronic devices connected to the USB Type-C device are the DRPs, the roles of the source and sink are selected irregularly, regardless of user's intention. Therefore, for example, even though a battery level of one of the electronic devices is low, that device might be selected as the source, thereby making it likely that the device might run out of battery immediately.

In view of the above problems, the technique described in Patent Document 1 refers to a remaining battery level of the electronic device selected as the source, performs a control to stop the power supply when the remaining battery level falls below a threshold value, and further enables a user to select the roles of the power supply and reception by a dedicated UI (User Interface).

### CITATION LIST

[Patent Document]

[Patent Document 1] Japanese Patent Application Laid-Open Publication No.

2018-185750

[Patent Document 2] Japanese Patent Application Laid-Open Publication No. 2018-106555

### SUMMARY OF THE INVENTION

### Problems to be Solved by the Invention

According to Patent Document 1, however, when the remaining battery level of the device selected as the source becomes low, the control to be performed is to stop the power supply alone, and unless the user changes the rolls thereafter, the battery of the device cannot be prevented from running out. Further, in order for the user to optimally change the rolls, it is necessary to check the remaining battery level of the connected device at any time, but this confirmation work is difficult.

Further, according to the technique described in Patent Document 2, when an electronic device 100, which is a DRP device, is connected to an external device 200 in a DFP/Source state, the electronic device 100 must perform PR_SWAP to change into the sink to enable the power reception. For this reason, the electronic device 100 has a system control unit 117. When the external device 200 accepts the PR_SWAP, the system control unit 117 determines whether the electronic device 100 needs the power reception. Specifically, the system control unit 117 acquires a voltage value of the battery from a power supply unit 120 of the electronic device 100, and determines that the power reception is necessary when it is determined that the voltage value of the battery is insufficient for supplying the power to each device of the electronic device 100. The system control unit 117 outputs to the power supply unit 120, a result of the determination of whether or not the power reception is necessary (see paragraph [0043] of Patent Document 2).

Additionally, a power supply control unit 124 in the power supply unit 120 is a control circuit that controls switching of a switch 123. When a communication unit 110 of the electronic device 100 acquires a signal indicating that PR_SWAP with the external device 200 is successful and that the power reception is determined to be necessary, the power control unit 124 controls the switch 123 to connect a VBUS terminal 101a and a power supply connection unit 121 (see paragraph [0048] of Patent Document 2).

As a result, when the switch 123a is in the connected state, the electric power transmitted from the external device 200 is received via the VBUS terminal 101a. Further, the received power is inputted to a battery 400 via the power supply connection unit 121 (see paragraph [0086] of Patent Document 2).

That is, in Patent Document 2, the rolls of the power supply and reception are changed.

However, Patent Document 2 merely describes that the electronic device 100 needs the power reception based only on the voltage value of the battery of the electronic device 100 itself. For this reason, as in Patent Document 1, it is not possible to efficiently change the rolls between the electronic device and the external device to be connected, so that it is not possible to operate both devices for a long time.

The present invention has been made in view of the above circumstances, and provides an electronic device and a method of controlling the electronic device capable of efficiently changing the rolls between the electronic device and the external device to be connected and enabling a long-time power supply and reception operation as compared with the conventional case of both devices.

### Means for Solving the Problems

In order to solve the above problems, one aspect of the present invention is an electronic device connectable to an external device by using a communication device and capable of supplying and receiving power to and from the external device. The electronic device includes: a battery; a power supply switch that supplies power from the battery to the external device; a power reception switch that receives power from the external device to the battery; a computation unit that performs setting of power supply and reception roles with the external device, which turns on either one of the power supply switch and the power reception switch, according to a result of comparison between a remaining battery level of the battery and a remaining battery level of a battery of the external device; and a power supply and reception management unit that, according to the setting of the power supply and reception roles with the external device, turns on the power supply switch when the electronic device becomes a source device, and turns on the power reception switch when the electronic device becomes a sink device.

Further, one aspect of the present invention is a method for controlling an electronic device connectable to an external device by using a communication device and capable of supplying and receiving power to and from the external device. The electronic device includes: a battery; a power supply switch that supplies power from the battery to the external device; and a power reception switch that receives power from the external device to the battery. The method includes: a computation step of performing setting of power supply and reception roles with the external device, which turns on either one of the power supply switch and the power reception switch, according to a result of comparison between a remaining battery level of the battery and a remaining battery level of a battery of the external device; and a power supply and reception management step of, according to the setting of the power supply and reception roles with the external device, turning on the power supply switch when the electronic device becomes a source device, and turning on the power reception switch when the electronic device becomes a sink device.

### Effects of the Invention

According to one aspect of the present invention, it is possible to provide an electronic device and a method of controlling the electronic device capable of efficiently changing the rolls between the electronic device and the external device to be connected and enabling a long-time power supply and reception operation as compared with the conventional case of both devices.

### BRIEF DESCRIPTION OF THE DRAWINGS

FIG. 1 is a configuration diagram of an electronic device according to an embodiment of the present invention.

FIG. 2 is a flowchart showing an operation in a first embodiment of the electronic device according to the embodiment of the present invention.

FIG. 3 is a flowchart showing an operation in a second embodiment of the electronic device according to the embodiment of the present invention.

FIG. 4 is a diagram showing a minimum configuration of the electronic device according to the embodiment of the present invention.

### MODE FOR CARRYING OUT THE INVENTION

Hereinafter, a configuration of an electronic device according to an embodiment of the present invention will be described in detail with reference to the drawings.

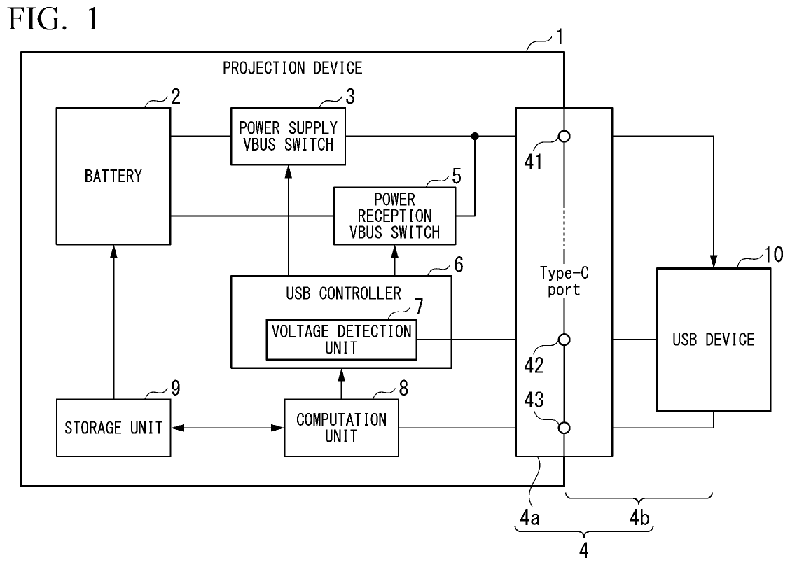

FIG. 1 is a configuration diagram of the electronic device according to the embodiment of the present invention.

As shown in FIG. 1, an electronic device 1 is a projection device that implements the present invention, and is mounted with a battery 2, a power supply VBUS switch (power supply switch 3), a Type-C port (communication device 4), and a power reception VBUS switch (power reception switch 5), a USB controller (power supply and reception management unit 6), a voltage detection unit 7, a computation unit 8, and a storage unit 9.

The battery 2 is a fixed power source, and supplies electric power to each device for operating the electronic device 1, that is, the devices (the power supply switch 3 to the storage unit 9) mounted on the electronic device 1.

When a USB device (external device 10) is an electronic device (external device 10) to be connected with the electronic device 1, a power supply to the connected device (external device 10) and a power reception from the connected device (external device 10) are enabled. Here, the present invention can be implemented as long as the connected device (external device 10) has at least a USB Type-C port (communication device corresponding to the communication device 4) and can support the DRP, such as a PC.

Here, the communication device 4 includes a connector 4a and a communication cable 4b having a plug for connecting to the connector 4a on one end side thereof. Further, a communication device of the external device 10 includes a connector corresponding to the connector 4a and a communication cable 4b having a plug for connecting to the connector on the other end side thereof.

It is assumed here that the connector 4a and the connector corresponding to the connector 4a are USB Type-C receptacles, respectively. Further, it is assumed that the communication cable 4b is a cable compliant with the USB Type-C standard.

That is, the electronic device 1 is an electronic device that is connected to the external device 10 by using the communication device 4 and can supply and receive power to and from the external device 10.

This power supply and reception requires performing a configuration of power supply and reception rolls (setting of the power supply and reception roles) in advance, and the power reception and reception management unit 6 pulls down and pulls up a resistor of the voltage detection unit 7. As a result of this operation, when the roll becomes the power supply (source), the power supply switch 3 is turned on, and when the roll becomes the power reception (sink), the power reception switch 5 is turned on. The power supply switch 3 and the power reception switch 5 are devices that control VBUS, which is a bus used to supply power to the communication device 4, and are operated by the power supply and reception management unit 6.

That is, the electronic device 1 includes the battery 2, the power supply switch 3, the communication device 4, the power reception switch 5, and the power supply and reception management unit 6.

The power supply switch 3 supplies power from the battery 2 to the external device 10 via a terminal 41 of the connector 4a and the communication cable 4b (VBUS which is the bus used for the power supply).

The power reception switch 5 receives power from the external device 10 to the battery 2 via the communication cable 4b (VBUS which is the bus used for the power supply) and the terminal 41 of the connector 4a.

As a result of setting the power supply and reception roles with the external device 10, the power supply and reception management unit 6 turns on the power supply switch 3 when the electronic device becomes the source device, and turns on the power reception switch 5 when the electronic device becomes the sink device.

Here, as in the electronic device 1, the external device 10 includes a battery corresponding to the battery 2, a power supply switch corresponding to the power supply switch 3, a power reception switch corresponding to the power reception switch 5, a communication device corresponding to the communication device 4, and a power supply and reception management unit corresponding to the power supply and reception management unit 6.

Then, in the setting of the power supply and reception roles, both the electronic device and the external device 10, which are connected by a terminal 42 of the connector 4a of the communication device 4 and a terminal of the external device 10 corresponding to the terminal 42, repeatedly perform the pull-up and pull-down operations of the resistors included in the voltage detection unit 7 of the power supply and reception management unit 6 mounted and a voltage detection unit of the power supply and reception management unit of the external device 10.

Thus, when the pull-up state and the pull-down state of the respective devices come to be relative to each other by the repetitive operations performed by connecting the terminal 42 of the connector 4a and the terminal of the external device 10 corresponding to the terminal 42, the operations are stopped so that the device stopped in the pull-up state becomes the source device in the power supply and reception role setting, and the device stopped in the pull-down state becomes the sink device.

Here, the power supply and reception management unit 6 is an ASIC (integrated circuit with semiconductor) that controls a USB port (communication device 4), and is controlled by a microcomputer mounted on the electronic device 1.

The supply and reception roles in the present invention are as described above, but the electronic device 1 performs remote access to the external device 10 which is the connected device by using the serial communication standard of the external device 10. By this remote access, an expansion operation of remaining battery level information is performed in a format according to an API (Application Programming Interface) of the connected device, thereby acquiring the remaining battery level information of the battery of the external device 10.

The computation unit 8 is a device that compares a remaining battery level of the battery 2 of the electronic device 1 acquired by the storage unit 9 with a remaining battery level of the battery of the external device 10 as the connected device. The computation unit 8 has a determination unit, and determines whether to switch the rolls based on a result of the comparison.

That is, the electronic device 1 has the storage unit 9, and the computation unit 8 has the determination unit which compares the remaining battery level of the battery which the storage unit 9 acquired from the battery 2 with the remaining battery level of the battery of the external device 10 as the connected device; and based on a result of the comparison, determines whether to switch the roles of the source device and the sink device in the power supply and reception role setting; and based on a result of the determination, controls the power supply and reception management unit 6 to perform the power supply and reception role setting with the external device 10. As a result, the power supply and reception management unit 6 turns on the power supply switch 3 when the electronic device is set as the source device, and turns on the power reception switch 5 when the electronic device is set as the sink device.

That is, the computation unit 8 performs the power supply and reception role setting with the external device 10, which turns on either the power supply switch 3 or the power reception switch 5 according to a result of the comparison between the remaining battery level of the battery 2 and the remaining battery level of the battery of the external device 10.

Further, according to the power supply and reception role setting with the external device 10, the power supply and reception management unit 6 turns on the power supply switch 3 when the electronic device becomes the source device, and turns on the power reception switch 5 when the electronic device becomes the sink device.

### First Embodiment

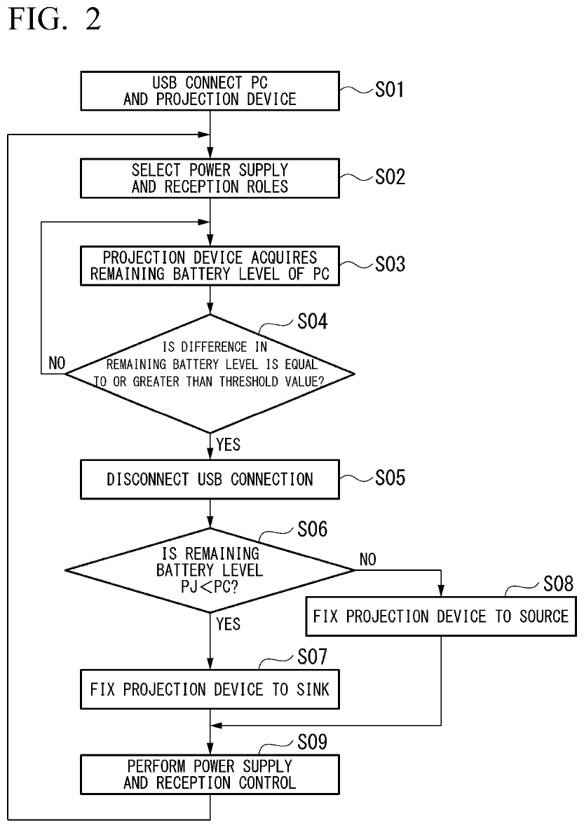

Next, an example (first embodiment) of the present invention will be described with reference to FIG. 2.

FIG. 2 is a flowchart showing an operation in the first embodiment of the electronic device according to the embodiment of the present invention.

A PC and a projection device are USB connected (step S01).

The electronic device 1 (projection device) and the external device 10 (PC) are connected by the USB Type-C device (communication device 4) of the electronic device 1. That is, it is premised that both connected devices are DRPs and are models that support the exchange of roles.

Power supply and reception rolls are selected (step S02).

Both devices to which the device (communication cable 4b of the communication device 4) is connected in step S01 repeatedly perform, for example, the pull-up and pull-down operations of the resistor included in the voltage detection unit 7, on the ASICs of the USB controllers (the power supply and reception management unit 6 and the power supply and reception management unit corresponding to the power supply and reception management unit 6) mounted on the respective devices. When the pull-up and the pull-down become relative to each other due to the repetitive operations, the operations are stopped, so that the device stopped in the pull-up state becomes the source device of the power supply and reception rolls, and the device stopped in the pull-down state becomes the sink device.

The projection device acquires the remaining battery level of the PC (step S03).

The computation unit 8 in the electronic device 1 acquires remaining battery level information of the PC (external device 10). The electronic device 1 (projection device) remotely accesses the PC (external device 10) via the serial bus of the device (communication device 4).

At this time, since a screen for requesting an approval of the connection of the projection device (electronic device 1) is displayed on a display screen of the PC (external device 10), the user inputs necessary information to this and makes a serial connection. The necessary information incudes, for example, a user name of the PC, a password, and the like. After the serial connection is completed, the projection device (electronic device 1) acquires the remaining battery level information of the PC (external device 10). As an acquisition means, a command prompt is expanded from the projection device (electronic device 1) according to the API of the PC (external device 10), and for example, character-type data, which is the displayed remaining battery level information, is stored in an information acquisition array and thus acquired, so that the projection device (electronic device 1), by analyzing the acquired data, retrieves the remaining battery level of the battery of the PC (external device 10).

That is, the computation unit 8 remotely accesses the external device 10 via the serial bus connected at the terminal 43 of the connector 4a to make the serial connection, acquires the remaining battery level information of the battery of the external device 10, and retrieves from the remaining battery level information, the remaining battery level of the battery of the external device, which is used for the determination by the determination unit.

It is determined whether a difference in remaining battery level is equal to or greater than a threshold value (step S04).

The computation unit 8 in the projection device (electronic device 1) compares the remaining battery level of the battery of the PC (external device 10) acquired in step S03 with the remaining battery level of the battery 2 of the projection device (electronic device 1). As a result of the comparison, if the difference in remaining battery level exceeds a preset threshold value, the process proceeds to step S05. If the difference is within the threshold value, step S03 is repeated.

The USB connection is disconnected (step S05).

As a result of the comparison, if the difference in remaining battery level exceeds the preset threshold value (step S04—Yes), the computation unit 8 determines that it is necessary to exchange the power supply and reception rolls, and thus controls the power supply and reception management unit 6 to turn off the on switch of the power supply switch 3 and the power reception switch 5, thus cutting off the connection between the external device 10 and the battery 2.

That is, the computation unit 8 controls the power supply and reception management unit 6 to turn off the on switch of the power supply switch 3 and the power reception switch 5, when the difference in remaining battery level, which is the result of the comparison between the remaining battery level of the battery 2 and the remaining battery level of the battery of the external device 10, is equal to or greater than the threshold value.

It is determined whether or not the remaining battery level is PJ<PC (step S06). Regarding the remaining battery levels of both devices, if the remaining battery level of the battery 2 of the projection device (electronic device 1) is less than the remaining battery level of the battery of the PC (external device 10) (step S06—Yes), the process proceeds to step S07. On the other hand, if the remaining battery level of the battery 2 of the projection device (electronic device 1) is greater than the remaining battery level of the battery of the PC (external device 10) (step S06—No), the process proceeds to step S08.

The projection device is fixed to the sink (step S07).

Since it has been determined that the remaining battery level of the projection device (electronic device 1) is less than the remaining battery level of the PC (external device 10) (step S06—Yes), it is necessary to supply power from the PC (external device 10) to the projection device (electronic device 1) for the purpose of equalizing the remaining battery levels of the respective electronic devices connected to the device (communication device 4). Therefore, the controller of the projection device (the power supply and reception management unit 6 of the electronic device 1) sets the roll as the sink.

The projection device is fixed to the source (step S08).

Since it has been determined that the remaining battery level of the projection device (electronic device 1) is greater than that of the PC (external device 10), it is necessary to supply power from the projection device (electronic device 1) to the PC (external device 10) for the same purpose as in step S07. Therefore, the controller of the projection device (the power supply and reception management unit 6 of the electronic device 1) sets the role as the source.

That is, the computation unit 8 compares the remaining battery level of the battery 2 with the remaining battery level of the battery of the external device 10, and controls the power supply and reception management unit 6 to turn on the power reception switch 5 when the remaining battery level of the battery 2 is less than the remaining battery level of the battery of the external device 10. On the other hand, the computation unit 8 controls the power supply and reception management unit 6 turn on the power supply switch 3 when the remaining battery level of the battery 2 is equal to or greater than the remaining battery level of the battery of the external device 10.

Power supply and reception control is performed (step S09).

The power supply and reception process is performed according to the power supply and reception rolls set in step S07 or step S08.

That is, from the result of the comparison in step S06, the computation unit 8 determines whether to switch the roles of the source device and the sink device in the power supply and reception role setting. Based on a result of the determination, the computation unit 8 controls the power supply and reception management unit 6 to set the supply and reception rolls. The power supply and reception management unit 6 turns on the power supply switch 3 when the electronic device 1 (own device) is set as the source device. On the other hand, the power supply and reception management unit 6 turns on the power reception switch 5 when the electronic device 1 is set as the sink device.

According to the electronic device 1 described in the first embodiment, the selection and change of the power supply and reception rolls in the USB Type-C standard are performed in consideration of the remaining battery level of the device connected to the electronic device. For this reason, charging is performed when the remaining battery level of one of the connected devices is low, so that a long-time power supply and reception operation is enabled as compared to the conventional case of both devices. Further, since the above-described processing is dynamically performed by the device mounted with the present invention, it is not necessary to check the remaining battery levels of both connected devices more than necessary.

That is, according to one aspect of the present invention, it is possible to provide an electronic device and a method of controlling the electronic device capable of efficiently changing the rolls between the electronic device and the external device to be connected and enabling a long-time power supply and reception operation as compared with the conventional case of both devices.

### Second Embodiment

Ideally, the roll swap of the power supply and reception (role exchange between the source device and the sink device) performed in the first embodiment is performed a small number of times because power consumption is generated due to this. However, every time the difference in remaining battery level exceeds the threshold value, the device with the higher remaining battery level is set as the source, and the device with the lower remaining battery level is set as the sink, so that wasteful power consumption is generated by performing the roll swap.

Therefore, in the second embodiment, the device with the larger battery consumption per fixed time is set as the sink, while the device with the smaller battery consumption is set as the source, and thereafter the remaining battery level of each device is distributed so as to maximize the operable time of the system including both devices.

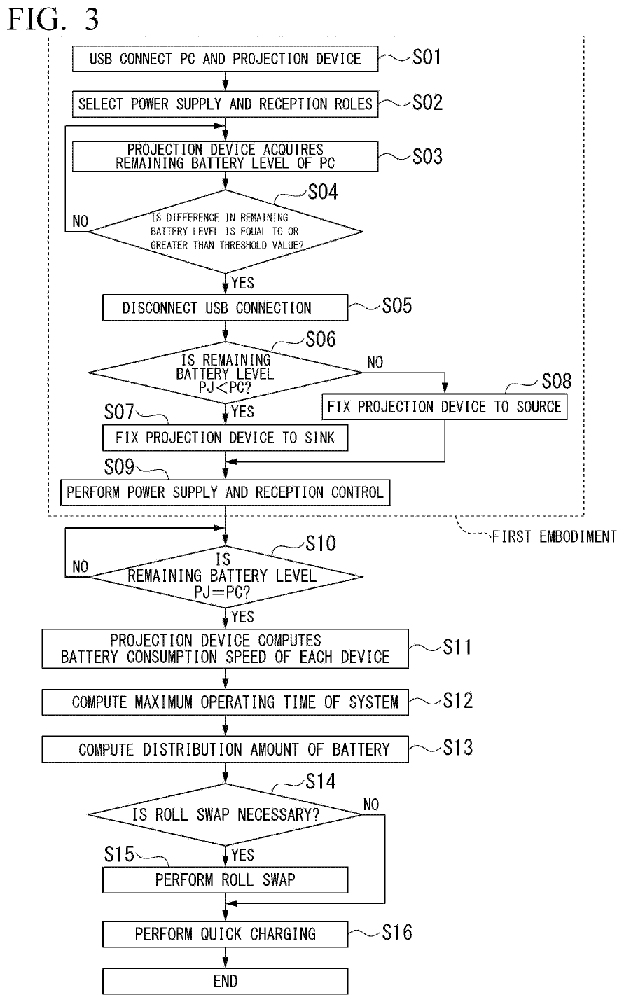

Hereinafter, an example (second embodiment) of the present invention will be described with reference to FIG. 3

FIG. 3 is a flowchart showing an operation in the second embodiment of the electronic device according to the embodiment of the present invention.

First, after operating both devices (electronic device 1 and external device 10) to some extent, the first embodiment is carried out to set the device with the larger remaining battery level as the source and set the other device as the sink to perform the power supply and reception (corresponding to the processes at steps S01 to S09).

Next, it is determined whether or not the remaining battery level is PJ=PC (step S10).

That is, it is determined whether or not the remaining battery levels of both devices have become equal by performing the power supply and reception shown in step S09. When the remaining battery levels become equal, the process proceeds to step S11.

When the second embodiment is carried out, it is necessary that the remaining battery levels of both devices are consumed to some extent, and when the remaining battery levels of both devices are distributed according to battery consumption speeds computed later, it is necessary to prevent the remaining battery level of the source side device from becoming extremely low. For this reason, the first embodiment is carried out to make the remaining battery levels of both devices substantially equal.

The projection device computes a battery consumption speed of each device (step S11).

The projection device (computation unit 8 of the electronic device 1) computes battery consumption speeds A and B of the projection device (electronic device 1) and the PC (external device 10). As a computation means, a battery consumption level per fixed time is extracted and substituted into the following formula 1 for computation. As the fixed time, the measurement for about 1 minute is preferable in order to maintain the relationship of the remaining battery levels equalized in step S10 as much as possible.

Battery Consumption Speed (V/min)=Battery Consumption Level/Measurement Time (Equation 1)

The maximum operating time of the system is computed (step S12).

The maximum time during which the image pickup device (electronic device 1) can maintain the operable state is defined as a maximum operating time Tmax of the system, which is computed using, for example, Equations 2 and 3.

T computed by Equation 2 is the total operable time of each device, and the value computed in step S11 is substituted into the battery consumption speed. That is, the remaining battery level and the battery consumption speed of the electronic device 1 are substituted as the remaining battery level A and the battery consumption speed A, while the remaining battery level and the battery consumption speed of the external device 10 are substituted as the remaining battery level B and the battery consumption speed B.

Further, V1 shown in Equation 3 is the consumption speed of the device with relatively faster battery consumption speed computed in step S11, while V2 is the consumption speed of the device with slower consumption speed.

T=(Remaining Battery Level A/Battery Consumption Speed A)+(Remaining Battery Level B/Battery Consumption Speed B) (Equation 2)

Maximum Operating Time Tmax of System=(T/2)−(V1/V2) (Equation 3)

A distribution amount of the battery is computed (step S13).

In order to distribute the remaining battery level of each device for the purpose of operating both devices at the maximum operating time Tmax of the system computed in step S12, a distribution amount is computed using Equation 4.

Distribution Amount=Remaining Battery Level−Battery Consumption Speed×Maximum Operating Time Tmax of System (Equation 4)

It is determined whether or not the roll swap is necessary (step S14).

From the setting of the power supply and reception rolls set in step S07 or step S08 of the first embodiment, it is determined whether or not further roll swap needs to be performed. The determination is made based on whether the device with the slower battery consumption speed computed in step S11 is set as the source and the other device is set as the sink. If the roll swap is necessary, the process proceeds to step S15, and if not, the process proceeds to step S16.

The roll swap is performed (step S15).

The USB connection is disconnected, and the current power supply and reception roll setting is reversed for setting. After the setting, the USB reconnection is performed.

Quick charging is performed (step S16).

The quick charging is performed with reference to the battery distribution amount computed in step S13, that is, the amount of power supply from the source side device to the sink side device.

That is, the computation unit 8 compares the remaining battery level of the battery 2 with the remaining battery level of the battery of the external device 10, and according to a result of the comparison, controls the power supply and reception management unit 6 to turn on any one of the power supply switch 3 and the power reception switch 5 (processes in steps S06 to S09). When the remaining battery level of the battery 2 and the remaining battery level of the battery of the external device 10 become equal, the computation unit 8 computes the battery consumption speed of the battery 2 and the battery consumption speed of the battery of the external device 10 (process in step S11).

The computation unit 8 determines whether or not it is in a first setting state where the device having the battery with the battery consumption speed that is the slower of the calculated battery consumption speeds is set as the source device, and the device having the battery with the faster battery consumption speed compared to the battery with the slower battery consumption speed is set as the sink device (process in step S14).

If it is in the first setting state, the computation unit 8 controls the power supply and reception management unit 6 to turn off one of the switches so as to enter a second setting state in which the first setting state is reversed, such that the device having the battery with the slower battery consumption speed is set as the sink device, and the device having the battery with the faster consumption speed is set as the source device (process in step S15).

Further, the computation unit 8 computes a time T, which is the total operable time of each device, by a formula “T=(Remaining Battery Level of Battery of Electronic Device/Battery Consumption Speed of Battery of Electronic Device)+(Remaining Battery Level of Battery of External Device/Battery Consumption Speed of Battery of External Device),” where Tmax is the maximum operating time of the system during which the electronic device can maintain the operable state after computing the battery consumption speeds. Further, the computation unit 8 computes the maximum operating time Tmax of the system by a formula “Tmax=(T/2)−(V1/V2),” where V2 is the battery consumption speed of the battery with the slower battery consumption speed of the computed battery consumption speeds, and V1 is the battery consumption speed of the battery with the faster battery consumption speed (process in step S12).

Then, the computation unit 8 computes a distribution amount, which is the distribution of the remaining battery level of the electronic device, by a formula “Distribution Amount=Remaining Battery Level of Battery of Electronic Device−Battery Consumption Speed of Battery of Electronic Device×Maximum Operating Time Tmax of System” (process in step S13), and controls, while referring to the computed distribution amount, the power supply and reception management unit 6 so as to perform quick charging when the electronic device is the source device (process in step S16).

As a result, it is possible to reduce the wasteful power consumption generated by performing the roll swap of the power supply and reception (role exchange between the source device and the sink device).

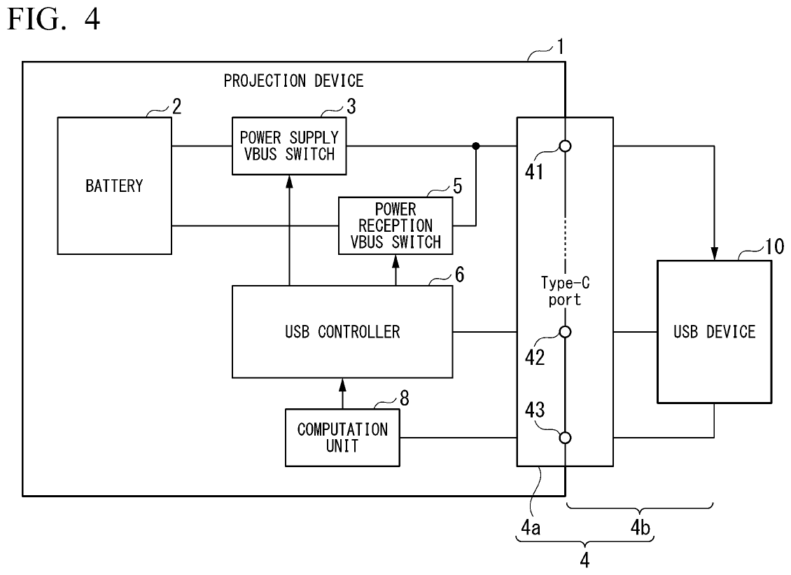

Next, a minimum configuration of the above embodiment will be described with reference to FIG. 4. FIG. 4 is a diagram showing the minimum configuration of an image display system according to the embodiment of the present invention.

The electronic device 1 is an electronic device which is connectable to the external device 10 by using the communication device 4, is capable of supplying and receiving power to and from the external device 10, and includes the battery 2, the power supply switch 3, the power reception switch 5, and the power supply and reception management unit 6, and the computation unit 8.

The power supply switch 3 supplies power from the battery 2 to the external device 10.

The power reception switch 5 receives power from the external device 10 to the battery 2.

The computation unit 8 performs setting of the power supply and reception roles with the external device 10, which turns on either the power supply switch 3 or the power reception switch 5, according to a result of comparison between the remaining battery level of the battery 2 and the remaining battery level of the battery of the external device 10.

According to the setting of the power supply and reception roles with the external device 10, the power supply and reception management unit 6 turns on the power supply switch 3 when the electronic device becomes the source device, and turns on the power reception switch 5 when the electronic device becomes the sink device.

As described above, according to the embodiment and the minimum configuration example of the present invention, it is possible to provide an electronic device and a method of controlling the electronic device capable of efficiently changing the rolls between the electronic device and the external device to be connected and enabling a long-time power supply and reception operation as compared with the conventional case of both devices.

As described above, the embodiment of the present invention has been described in detail with reference to the drawings, but the specific configuration is not limited to this embodiment, and a design and the like within a range not deviating from the gist of the present invention are also included. In addition, a part or all of programs executed by a computer such as one or more CPUs of the above embodiment can be distributed via a communication line or a computer-readable recording medium.

### DESCRIPTION OF REFERENCE NUMERALS

1 . . . electronic device
2 . . . battery
3 . . . power supply switch
4 . . . communication device
4a . . . connector
4b . . . communication cable
41, 42, 43 . . . terminal
5 . . . power reception switch
6 . . . power supply and reception management unit
7 . . . voltage detection unit
8 . . . computation unit
9 . . . storage unit
10 . . . external device

1. An electronic device connectable to an external device by using a communication device and capable of supplying and receiving power to and from the external device, the electronic device comprising:
a battery;
a power supply switch that supplies power from the battery to the external device;
a power reception switch that receives power from the external device to the battery;
a computation unit that performs setting of power supply and reception roles with the external device, which turns on either one of the power supply switch and the power reception switch, according to a result of comparison between a remaining battery level of the battery and a remaining battery level of a battery of the external device; and
a power supply and reception management unit that, according to the setting of the power supply and reception roles with the external device, turns on the power supply switch when the electronic device becomes a source device, and turns on the power reception switch when the electronic device becomes a sink device.

2. The electronic device of claim 1, wherein the computation unit
controls the power supply and reception management unit to turn off an on switch of the power supply switch and the power reception switch, when a difference between the remaining battery level of the battery and the remaining battery level of the battery of the external device, which is the result of the comparison, is equal to or greater than a threshold value,
compares the remaining battery level of the battery with the remaining battery level of the battery of the external device,
controls the power supply and reception management unit to turn on the power reception switch when the remaining battery level of the battery is less than the remaining battery level of the battery of the external device, and
controls the power supply and reception management unit to turn on the power supply switch when the remaining battery level of the battery is equal to or greater than the remaining battery level of the battery of the external device.

3. The electronic device of claim 1, wherein the computation unit
compares the remaining battery level of the battery with the remaining battery level of the battery of the external device, and according to the result of the comparison, controls the power supply and reception management unit to turn on either one of the power reception switch and the power supply switch, thereafter
computes a battery consumption speed of the battery and a battery consumption speed of the battery of the external device when the remaining battery level of the battery and the remaining battery level of the battery of the external device become equal, determines whether or not it is in a first setting state in which a device having the battery with a slower battery consumption speed of the computed battery consumption speeds is set as the source device, and a device having the battery with a faster battery consumption speed compared to the battery with the slower battery consumption speed is set as the sink device,
when it is in the first setting state, controls the power supply and reception management unit to turn off the one of the switches to enter a second setting state in which the first setting state is reversed, such that the device having the battery with the slower battery consumption speed is set as the sink device, and the device having the battery with the faster battery consumption speed compared to the battery with the slower battery consumption speed is set as the source device.

4. The electronic device of claim 3, wherein the computation unit, after computing the battery consumption speeds,
computes a time T, which is a total operable time of each device, by a formula “T=(the remaining battery level of the battery of the electronic device/the battery consumption speed of the battery of the electronic device)+(the remaining battery level of the battery of the external device/the battery consumption speed of the battery of the external device),” and
computes the maximum operating time Tmax of the system by a formula “Tmax=(T/2)−(V1/V2),” where Tmax is a maximum operating time of the system during which the electronic device can maintain an operable stat; V2 is the battery consumption speed of the battery with the slower battery consumption speed of the computed battery consumption speeds, and V1 is the battery consumption speed of the battery with the faster battery consumption speed compared to the battery with the slower battery consumption speed.

5. The electronic device of claim 4, wherein the computation unit
computes a distribution amount, which is distribution of the remaining battery level of the electronic device, by a formula “the distribution amount=the remaining battery level of the battery of the electronic device−the battery consumption speed of the battery of the electronic device×the maximum operating time Tmax of the system,” and
controls, while referring to the computed distribution amount, the power supply and reception management unit so as to perform quick charging when the electronic device is the source device.

6. The electronic device of claim 1, wherein
in the setting of the power supply and reception roles, both the electronic device and the external device which are connected by the communication device repetitively perform pull-up and pull-down operations of resistors included in a voltage detection unit of the power supply and reception management unit and a voltage detection unit of a power supply and a reception management unit of the external device, and stop the operations when a pull-up state and a pull-down state of the electronic device and the external device become relative to each other by the repetitive operations, and
a device stopped in the pull-up state becomes the source device in the setting of the power supply and reception roles, and a device stopped in the pull-down state becomes the sink device.

7. The electronic device of claim 1, further comprising:
a memory unit,
wherein the computation unit
comprises a determination unit,
compares, by the determination unit, the remaining battery level of the battery that the storage unit acquires from the battery with the remaining battery level of the battery of the external device to be connected,
determines, from a result of the comparison, whether to switch the roles of the source device and the sink device in the setting of the power supply and reception roles, and
controls, according to a result of the determination, the power supply and reception management unit to perform the setting of the power supply and reception roles with the external device, and
the power supply and reception management unit turns on the power supply switch when the electronic device is set as the source device, and turns on the power reception switch when the electronic device is set as the sink device.

8. The electronic device of claim 7, wherein the computation unit
remotely accesses the external device via a serial bus connected by the communication device to make a serial connection,
acquires battery remaining level information of the battery of the external device,
retrieves the remaining battery level of the battery of the external device from the battery remaining level information, and
uses the retrieved remaining battery level for the determination by the determination unit.

9. The electronic device of claim 1, wherein the communication device comprises
a connector compliant with a USB Type-C standard, and
a communication cable compliant with the USB Type-C standard that has a plug for connecting to the connector on one end of the communication cable.

10. A method for controlling an electronic device connectable to an external device by using a communication device and capable of supplying and receiving power to and from the external device, the electronic device comprising: a battery; a power supply switch that supplies power from the battery to the external device; and a power reception switch that receives power from the external device to the battery, the method comprising:
performing setting of power supply and reception roles with the external device, which turns on either one of the power supply switch and the power reception switch, according to a result of comparison between a remaining battery level of the battery and a remaining battery level of a battery of the external device; and
according to the setting of the power supply and reception roles with the external device, turning on the power supply switch when the electronic device becomes a source device, and turning on the power reception switch when the electronic device becomes a sink device.

11. The method of claim 10, further comprising:
turning off an on switch of the power supply switch and the power reception switch, when a difference between the remaining battery level of the battery and the remaining battery level of the battery of the external device, which is the result of the comparison, is equal to or greater than a threshold value;
comparing the remaining battery level of the battery with the remaining battery level of the battery of the external device;
turning on the power reception switch when the remaining battery level of the battery is less than the remaining battery level of the battery of the external device; and
turning on the power supply switch when the remaining battery level of the battery is equal to or greater than the remaining battery level of the battery of the external device.

12. The method of claim 10, further comprising:
comparing the remaining battery level of the battery with the remaining battery level of the battery of the external device to turn on either one of the power reception switch and the power supply switch according to the result of the comparison;
computing a battery consumption speed of the battery and a battery consumption speed of the battery of the external device when the remaining battery level of the battery and the remaining battery level of the battery of the external device become equal;
determining whether or not it is in a first setting state in which a device having the battery with a slower battery consumption speed of the computed battery consumption speeds is set as the source device, and a device having the battery with a faster battery consumption speed compared to the battery with the slower battery consumption speed is set as the sink device;
when it is in the first setting state, turning off the one of the switches to enter a second setting state in which the first setting state is reversed, such that the device having the battery with the slower battery consumption speed is set as the sink device, and the device having the battery with the faster battery consumption speed compared to the battery with the slower battery consumption speed is set as the source device.

13. The method of claim 12, further comprising, after computing the battery consumption speeds:
computing a time T, which is a total operable time of each device, by a formula “T=(the remaining battery level of the battery of the electronic device/the battery consumption speed of the battery of the electronic device)+(the remaining battery level of the battery of the external device/the battery consumption speed of the battery of the external device)”; and
computing the maximum operating time Tmax of the system by a formula “Tmax=(T/2)−(V1/V2),” where Tmax is a maximum operating time of the system during which the electronic device can maintain an operable state, V2 is the battery consumption speed of the battery with the slower battery consumption speed of the computed battery consumption speeds, and V1 is the battery consumption speed of the battery with the faster battery consumption speed compared to the battery with the slower battery consumption speed.

14. The method of claim 13, further comprising:
computing a distribution amount, which is distribution of the remaining battery level of the electronic device, by a formula “the distribution amount=the remaining battery level of the battery of the electronic device−the battery consumption speed of the battery of the electronic device×the maximum operating time Tmax of the system”; and
while referring to the computed distribution amount, performing quick charging when the electronic device is the source device.

15. The method of claim 10, further comprising:
in performing the setting of the power supply and reception roles with the external device, repetitively performing pull-up and pull-down operations of resistors included in the electronic device and the external device;
stop the operations when a pull-up state and a pull-down state of the electronic device and the external device become relative to each other by the repetitive operations; and
setting a device stopped in the pull-up state as the source device, and setting a device stopped in the pull-down state as the sink device.

16. The method of claim 10, further comprising:
comparing the remaining battery level of the battery that the storage unit acquires from the battery with the remaining battery level of the battery of the external device to be connected;
determining, from a result of the comparison, whether to switch the roles of the source device and the sink device in the setting of the power supply and reception roles;
performing the setting of the power supply and reception roles with the external device; and
turning on the power supply switch when the electronic device is set as the source device, and turning on the power reception switch when the electronic device is set as the sink device.

17. The method of claim 16, further comprising:
remotely accessing the external device via a serial bus connected by the communication device to make a serial connection;
acquiring battery remaining level information of the battery of the external device;
retrieving the remaining battery level of the battery of the external device from the battery remaining level information; and
using the retrieved remaining battery level for the determining.

18. The method of claim 10, wherein the communication device comprises
a connector compliant with a USB Type-C standard, and
a communication cable compliant with the USB Type-C standard that has a plug for connecting to the connector on one end of the communication cable.
